(19) United States
(12) Patent Application Publication
(10) Pub. No.: US 2026/0082885 A1
(43) Pub. Date: Mar. 19, 2026

(54) SEMICONDUCTOR PACKAGE STRUCTURE AND METHOD FOR FORMING THE SAME

(71) Applicant: JCET Microelectronics (Jiangyin) Co., LTD., Jiangyin (CN)

(72) Inventors: Qingyun ZHOU, Jiangyin (CN); Haijie CHEN, Jiangyin (CN); Qiang ZHAO, Jiangyin (CN); Yao LI, Jiangyin (CN); Ming SHENG, Jiangyin (CN)

(73) Assignee: JCET Microelectronics (Jiangyin) Co., LTD., Jiangyin (CN)

(21) Appl. No.: 19/323,692

(22) Filed: Sep. 9, 2025

(30) Foreign Application Priority Data
Sep. 19, 2024 (CN) 202411308055.9

(51) Int. Cl. H10W 20/20; H10W 70/652; H10W 74/15; H10W 90/00

(52) U.S. Cl. CPC H10W 20/20; H10W 90/00; H10W 70/6528; H10W 74/15; H10W 90/724; H10W 90/733; H10W 90/734; H10W 90/794

(57) ABSTRACT

A semiconductor package method includes: providing a first carrier board, forming a first molding layer covering the upper surface of the first carrier board and the bridge chip after bonding an upper insulation layer of the bridge chip on the upper surface of the first carrier board; thinning the first molding layer and the lower insulation layer, and forming a first redistribution layer on the surfaces of the thinned first molding layer and lower insulation layer, the process for forming the first redistribution layer includes an electroplating process; thinning the upper insulation layer and the first molding layer, forming a second redistribution layer on the surfaces of the thinned upper insulation layer and first molding layer, and the process for forming the second redistribution layer includes an electroplating process; and providing a semiconductor chip, mounting the semiconductor chip on the upper surface of the second redistribution layer, and the semiconductor chip being electrically connected with the second redistribution layer.

### CROSS-REFERENCE TO RELATED APPLICATIONS

This application claims the benefit of priority to Chinese Application No. 202411308055.9, filed Sep. 19, 2024, which is incorporated herein by reference in its entirety.

### TECHNICAL FIELD

The present disclosure relates to the field of semiconductor package, and particularly relates to a semiconductor package structure and a method for forming the same.

### BACKGROUND

In order to achieve better performance, maintain a smaller volume, and lower power consumption, existing package technology has evolved from early 2D package toward 2.5D package and 3D package. Embedded Bridge Die technology is also increasingly applied in 2.5D package and 3D package.

### SUMMARY

In one aspect, the present disclosure provides a method for forming a semiconductor package structure, comprising: providing a bridge chip, the bridge chip comprising a substrate, the substrate comprising opposed front surface and back surface, the front surface of the substrate having a pad, the substrate having in it a through-hole connection structure, the back surface of the substrate exposing a surface of one end of the through-hole connection structure; and the bridge chip further comprises: a first metal pillar protruding on the front surface of the substrate and electrically connected with the corresponding pad; an upper insulation layer covering the first metal pillar and the front surface of the substrate; a second metal pillar protruding on the back surface of the substrate and electrically connected with the corresponding through-hole connection structure; and a lower insulation layer covering the second metal pillar and the back surface of the substrate; providing a first carrier board, bonding the upper insulation layer of the bridge chip on the upper surface of the first carrier board; forming a first molding layer covering the upper surface of the first carrier board and the bridge chip; thinning a surface of the first molding layer facing away from the first carrier board, exposing a surface of one end of the second metal pillar facing away from the back surface of the substrate; forming a first redistribution layer on the surface of the thinned first molding layer, the first redistribution layer being electrically connected with the second metal pillar, the process for forming the first redistribution layer comprising an electroplating process; providing a second carrier board, bonding the first redistribution layer on the upper surface of the second carrier board; removing the first carrier board, exposing the upper insulation layer; thinning a surface of the first molding layer facing away from the second carrier board, exposing a surface of one end of the first metal pillar facing away from the front surface of the substrate; forming a second redistribution layer on the surface of the thinned first molding layer, the second redistribution layer being electrically connected with the first metal pillar, the process for forming the second redistribution layer comprising an electroplating process; providing a semiconductor chip, mounting the semiconductor chip on the upper surface of the second redistribution layer, the semiconductor chip being electrically connected with the second redistribution layer; and forming a second molding layer covering the upper surface of the second redistribution layer and the semiconductor chip.

In an optional embodiment, it further comprises: removing the second carrier board, exposing the first redistribution layer; forming, on the lower surface of the first redistribution layer, a solder bump electrically connected with the first redistribution layer.

In an optional embodiment, the first redistribution layer comprises a first organic dielectric layer and a first metal line layer located in the first organic dielectric layer; the first organic dielectric layer being a single-layer or multi-layer stacked structure, and the corresponding first metal line layer being a single-layer or multi-layer stacked structure; and the first redistribution layer being electrically connected with the second metal pillar comprises: the first metal line layer being electrically connected with the second metal pillar.

In an optional embodiment, when the first organic dielectric layer and the first metal line layer are both one layer, the formation process of the first redistribution layer comprises: forming a first organic dielectric layer on the surface of the thinned first molding layer and the lower insulation layer using a coating process; performing an exposure process, a development process, and a thermal curing process on the first organic dielectric layer formed by coating, forming, in the first organic dielectric layer, a first opening exposing a surface of one end of the second metal pillar; forming a seed layer on the upper surface of the first organic dielectric layer and on the sidewalls and the bottom surface of the first opening; forming a photoresist layer on the upper surface of the seed layer; patterning the photoresist layer to form, in the photoresist layer, a second opening exposing the seed layer in the first opening and a portion of the upper surface of the seed layer on the outer side of the first opening; forming a first metal line layer in the second opening using an electroplating process; and removing the photoresist layer.

In an optional embodiment, the second redistribution layer comprises a second organic dielectric layer and a second metal line layer located in the second organic dielectric layer; the second organic dielectric layer being a single-layer or multi-layer stacked structure, and the corresponding second metal line layer being a single-layer or multi-layer stacked structure; and the second redistribution layer further comprises micro pads located on the top surface of the second organic dielectric layer and electrically connected with the second metal line layer.

In an optional embodiment, the semiconductor chip is mounted on the upper surface of the second redistribution layer, the semiconductor chip being electrically connected with the second redistribution layer comprises: micro bumps on the semiconductor chip being soldered together with the micro pads; the second redistribution layer being electrically connected with the first metal pillar comprises: the second metal line layer being electrically connected with the first metal pillar.

In an optional embodiment, it further comprises: forming a columnar connection structure on the upper surface of the first carrier board on one side or more sides of the bridge chip before forming the first molding layer; the first molding layer further covering the columnar connection structure; and the first redistribution layer and the second redistribution layer being further electrically connected with the columnar connection structure.

In an optional embodiment, the substrate of the bridge chip further has a redistribution layer on a front surface of the substrate, the redistribution layer being a part of the substrate; the pads are located on the upper surface of the redistribution layer and are electrically connected with the redistribution layer; and the through-hole connection structure is electrically connected with the redistribution layer.

In an optional embodiment, the redistribution layer comprises a passivation layer and a metal line layer located in the passivation layer; the passivation layer being a single-layer or multi-layer stacked structure, and the corresponding metal line layer being a single-layer or multi-layer stacked structure; the pad being electrically connected with the metal line layer.

In an optional embodiment, a deep trench capacitor is further formed in the substrate of the bridge chip, the deep trench capacitor being electrically connected with the redistribution layer.

In an optional embodiment, the process for forming the bridge chip comprises: providing a substrate; forming a through-hole connection structure and a deep trench capacitor in the substrate; forming a redistribution layer on a front surface of the substrate; forming pads on an upper surface of the redistribution layer; forming a protruding first metal pillar on the upper surface of the pads; forming an upper insulation layer covering the first metal pillar and the front surface of the substrate; thinning the back surface of the substrate, exposing a surface of one end of the through-hole connection structure; forming a protruding second metal pillar on the exposed surface of the through-hole connection structure; forming a lower insulation layer covering the second metal pillar and the back surface of the substrate; and cutting the substrate to form a number of discrete bridge chips.

In another aspect, the present disclosure also provides a method for forming a semiconductor package structure, comprising: providing a bridge chip, the bridge chip comprising a substrate, the substrate comprising opposed front surface and back surface, the front surface of the substrate having a pad, the substrate having in it a through-hole connection structure, the back surface of the substrate exposing a surface of one end of the through-hole connection structure; and the bridge chip further comprises: a first metal pillar protruding on the front surface of the substrate and electrically connected with the corresponding pad; a second metal pillar protruding on the back surface of the substrate and electrically connected with the corresponding through-hole connection structure; and a lower insulation layer covering the second metal pillar and the back surface of the substrate; providing a carrier board, bonding the lower insulation layer of the bridge chip on the upper surface of the carrier board; forming a first molding layer covering the upper surface of the carrier board and the bridge chip and filling between the first metal pillars; thinning a surface of the first molding layer facing away from the carrier board, exposing a surface of one end of the first metal pillar facing away from the front surface of the substrate; forming a upper redistribution layer on the surface of the thinned first molding layer, the upper redistribution layer being electrically connected with the first metal pillar, the process for forming the upper redistribution layer comprising an electroplating process; providing a semiconductor chip, mounting the semiconductor chip on the upper surface of the upper redistribution layer, the semiconductor chip being electrically connected with the upper redistribution layer; forming a second molding layer covering the upper surface of the upper redistribution layer and the semiconductor chip; removing the carrier board to expose the lower insulation layer; and forming, on the lower insulation layer, a solder bump electrically connected with the second metal pillar.

In yet another aspect, the present disclosure provides a method for forming a semiconductor package structure, comprising: providing a bridge chip, the bridge chip comprising a substrate, the substrate comprising opposed front surface and back surface, the front surface of the substrate having a pad, the substrate having in it a through-hole connection structure, the back surface of the substrate exposing a surface of one end of the through-hole connection structure; and the bridge chip further comprises: a first metal pillar protruding on the front surface of the substrate and electrically connected with the corresponding pad; an upper insulation layer covering the first metal pillar and the front surface of the substrate; a second metal pillar protruding on the back surface of the substrate and electrically connected with the corresponding through-hole connection structure; and a lower insulation layer covering the second metal pillar and the back surface of the substrate; providing a first carrier board, bonding the lower insulation layer of the bridge chip on the upper surface of the first carrier board; forming a first molding layer covering the upper surface of the first carrier board and the bridge chip; thinning a surface of the first molding layer facing away from the first carrier board, exposing a surface of one end of the second metal pillar facing away from the front surface of the substrate; forming a first redistribution layer on the thinned surface of the first molding layer and the lower insulation layer, the first redistribution layer being electrically connected with the first metal pillar, the process for forming the first redistribution layer comprising an electroplating process; providing a second carrier board, bonding the first redistribution layer on the upper surface of the second carrier board; removing the first carrier board, exposing the lower insulation layer; thinning a surface of the first molding layer facing away from the second carrier board, exposing a surface of one end of the second metal pillar facing away from the back surface of the substrate; forming a second redistribution layer on the thinned surface of the upper insulation layer and the first molding layer, the second redistribution layer being electrically connected with the second metal pillar, the process for forming the second redistribution layer comprising an electroplating process; providing a semiconductor chip, mounting the semiconductor chip on the upper surface of the second redistribution layer, the semiconductor chip being electrically connected with the second redistribution layer; forming a second molding layer covering the upper surface of the second redistribution layer and the semiconductor chip; and removing the second carrier board and forming, on a lower surface of the first redistribution layer, a solder bump electrically connected with the first redistribution layer.

In yet another aspect, the present disclosure also provides a semiconductor package structure, comprising: a bridge chip, the bridge chip comprising a substrate, the substrate comprising opposed front surface and back surface, the front surface of the substrate having a pad, the substrate having in it a through-hole connection structure, the back surface of the substrate exposing a surface of one end of the through-hole connection structure; and the bridge chip further comprises: a first metal pillar protruding on the front surface of the substrate and electrically connected with the corresponding pad; an upper insulation layer covering the first metal pillar and the front surface of the substrate, an upper surface of the upper insulation layer exposing a surface of one end of the first metal pillar facing away from the front surface of the substrate; a second metal pillar protruding on the back surface of the substrate and electrically connected with the corresponding through-hole connection structure; a lower insulation layer covering the second metal pillar and the back surface of the substrate, a lower surface of the lower insulation layer exposing a surface of one end of the second metal pillar facing away from the back surface of the substrate; a first molding layer covering the bridge chip, the upper surface of the first molding layer exposing the upper surface of the upper insulation layer and the surface of one end of the first metal pillar facing away from the front surface of the substrate, the lower surface of the first molding layer exposing the lower surface of the lower insulation layer and the surface of one end of the second metal pillar facing away from the back surface of the substrate; a first redistribution layer located on the lower surface of the first molding layer and the lower insulation layer, the first redistribution layer being electrically connected with the second metal pillar; a second redistribution layer located on the upper surface of the first molding layer and the upper insulation layer, the second redistribution layer being electrically connected with the first metal pillar; a semiconductor chip, the semiconductor chip being mounted on the upper surface of the second redistribution layer, the semiconductor chip being electrically connected with the second redistribution layer; and a second molding layer covering the upper surface of the second redistribution layer and the semiconductor chip.

In an optional embodiment, the heights of the first metal pillar and the second metal pillar are the same.

In an optional embodiment, the first redistribution layer comprises a first organic dielectric layer and a first metal line layer located in the first organic dielectric layer; the first organic dielectric layer is a single-layer or multi-layer stacked structure, and the corresponding first metal line layer is a single-layer or multi-layer stacked structure; and the first redistribution layer being electrically connected with the second metal pillar comprises: the first metal line layer being electrically connected with the second metal pillar.

In an optional embodiment, the second redistribution layer comprises a second organic dielectric layer and a second metal line layer located in the second organic dielectric layer; the second organic dielectric layer is a single-layer or multi-layer stacked structure, and the corresponding second metal line layer is a single-layer or multi-layer stacked structure; and the second redistribution layer further comprises micro pads located on the upper surface of the second organic dielectric layer on the top layer and electrically connected with the second metal line layer.

In an optional embodiment, the semiconductor chip is mounted on the upper surface of the second redistribution layer, the semiconductor chip being electrically connected with the second redistribution layer comprises: micro bumps on the semiconductor chip being soldered together with the micro pads; the second redistribution layer being electrically connected with the first metal pillar comprises: the second metal line layer being electrically connected with the first metal pillar.

In an optional embodiment, it further comprises: a columnar connection structure located on one side or more sides of the bridge chip; the first molding layer further covering the columnar connection structure; and the first redistribution layer and the second redistribution layer being further electrically connected with the columnar connection structure.

In an optional embodiment, the substrate of the bridge chip further has a redistribution layer on a front surface of the substrate, the redistribution layer being a part of the substrate; the pads are located on the upper surface of the redistribution layer and are electrically connected with the redistribution layer; and the through-hole connection structure is electrically connected with the redistribution layer.

In an optional embodiment, the redistribution layer comprises a passivation layer and a metal line layer located in the passivation layer; the passivation layer being a single-layer or multi-layer stacked structure, and the corresponding metal line layer being a single-layer or multi-layer stacked structure; the pad being electrically connected with the metal line layer.

In an optional embodiment, a deep trench capacitor is further formed in the substrate of the bridge chip, the deep trench capacitor being electrically connected with the redistribution layer.

In an optional embodiment, an underfill layer is further filled between the semiconductor chip and the upper surface of the second redistribution layer.

In an optional embodiment, the materials of the upper insulation layer and the lower insulation layer are the same.

In an optional embodiment, the material of the upper insulation layer and the lower insulation layer are molding materials or organic insulation dielectric materials.

In yet another aspect, the present disclosure also provides a semiconductor package structure, comprising: a bridge chip, the bridge chip comprising a substrate, the substrate comprising opposed front surface and back surface, the front surface of the substrate having a pad, the substrate having in it a through-hole connection structure, the back surface of the substrate exposing a surface of one end of the through-hole connection structure; and the bridge chip further comprises: a first metal pillar protruding on the front surface of the substrate and electrically connected with the corresponding pad; a second metal pillar protruding on the back surface of the substrate and electrically connected with the corresponding through-hole connection structure; a lower insulation layer covering the second metal pillar and the back surface of the substrate; a first molding layer covering the bridge chip and filling between the first metal pillars, the upper surface of the first molding layer exposing the surface of one end of the first metal pillar facing away from the front surface of the substrate, the lower surface of the first molding layer exposing the surface of one end of the second metal pillar facing away from the back surface of the substrate; an upper redistribution layer located on the upper surface of the first molding layer, the upper redistribution layer being electrically connected with the first metal pillar; a semiconductor chip, the semiconductor chip being mounted on the upper surface of the upper redistribution layer, the semiconductor chip being electrically connected with the upper redistribution layer; a second molding layer covering the upper surface of the upper redistribution layer and the semiconductor chip; and a solder bump located on the lower insulation layer and electrically connected with the second metal pillar.

In yet another aspect, the present disclosure also provides a semiconductor package structure, comprising: a bridge chip, the bridge chip comprising a substrate, the substrate comprising opposed front surface and back surface, the front surface of the substrate having a pad, the substrate having in it a through-hole connection structure, the back surface of the substrate exposing a surface of one end of the through-hole connection structure; and the bridge chip further comprises: a first metal pillar protruding on the front surface of the substrate and electrically connected with the corresponding pad; an upper insulation layer covering the first metal pillar and the front surface of the substrate; a second metal pillar protruding on the back surface of the substrate and electrically connected with the corresponding through-hole connection structure; a lower insulation layer covering the second metal pillar and the back surface of the substrate; a first molding layer covering the bridge chip, the upper surface of the first molding layer exposing the surface of one end of the second metal pillar facing away from the front surface of the substrate, the lower surface of the first molding layer exposing the surface of one end of the first metal pillar facing away from the back surface of the substrate; a first redistribution layer located on the lower surface of the first molding layer and the upper insulation layer, the first redistribution layer being electrically connected with the first metal pillar; a second redistribution layer located on the upper surface of the upper insulation layer and the first molding layer, the second redistribution layer being electrically connected with the second metal pillar; a semiconductor chip, the semiconductor chip being mounted on the upper surface of the second redistribution layer, the semiconductor chip being electrically connected with the second redistribution layer; a second molding layer covering the upper surface of the second redistribution layer and the semiconductor chip; and a solder bump located on a lower surface of the first redistribution layer and electrically connected with the first redistribution layer.

### BRIEF DESCRIPTION OF THE DRAWINGS

FIG. 1, FIGS. 8-15 are structural schematic diagrams of the formation process of a semiconductor package structure in one embodiment of the present disclosure;

FIGS. 2-7 are structural schematic diagrams of the formation process of a bridge chip in one embodiment of the present disclosure;

FIG. 16 is a structural schematic diagram of the formation process of a semiconductor package structure in another embodiment of the present disclosure; and

FIG. 17 is a structural schematic diagram of the formation process of a semiconductor package structure in yet another embodiment of the present disclosure.

### DETAILED DESCRIPTION

Specific embodiments of the present disclosure are described in detail below in conjunction with the accompanying drawings. When detailing the embodiments of the present disclosure, the schematic drawings will not be partially enlarged in accordance with the general proportion for the convenience of illustration, and the schematic drawings are only examples, which shall not limit the scope of protection of the present disclosure herein. In addition, the three-dimensional spatial dimensions of length, width and depth should be included in the actual production.

In the existing package structure with embedded bridge die, the micro bumps on the bridge die and the micro pads on the interposer located under the bridge die are generally welded and fixed by solder (e.g., solder tin), and this fixing method, in the process of package, due to the existence of multiple thermal curing processes, makes it prone to having defects such as voids and/or cracks at the soldering points of the micro bumps on the bridge die and the micro pads on the interposer, which reduces the connection strength at the soldering points and affects the reliability of the package structure.

The technical problem to be solved by the present disclosure is to provide a semiconductor package structure and a method for forming the same, which improve the connection strength at the connection points of a bridge chip and a wiring layer, and which improve the reliability of the package structure.

Compared with the existing technology, the advantages of the technical solution of the present disclosure include the following.

In the semiconductor package structure and the method for forming the same in the aforementioned embodiments of the present disclosure, in one embodiment, a first carrier board is provided, after bonding an upper insulation layer of the bridge chip on the upper surface of the first carrier board, a first molding layer covering the upper surface of the first carrier board and the bridge chip is formed; the first molding layer and the lower insulation layer are thinned to expose a surface of one end of the second metal pillar facing away from the back surface of the substrate; a first redistribution layer is formed on the thinned surface of the first molding layer and the lower insulation layer, the first redistribution layer being electrically connected with the second metal pillar, the process for forming the first redistribution layer including an electroplating process; a second carrier board is provided, the first redistribution layer is bonded on the upper surface of the second carrier board; the first carrier board is removed to expose the upper insulation layer; a thinning of the upper insulation layer and the first molding layer is performed to expose the surface of one end of the first metal pillar facing away from the front surface of the substrate; a second redistribution layer is formed on the thinned surface of the upper insulation layer and the first molding layer, the second redistribution layer being electrically connected with the first metal pillar, and the process for forming the second redistribution layer includes an electroplating process; a semiconductor chip is provided, the semiconductor chip is bonded on the upper surface of the second redistribution layer, the semiconductor chip being electrically connected with the second redistribution layer; and a second molding layer covering the upper surface of the second redistribution layer and the semiconductor chip is formed. The connection terminals with the outside on the front surface and back surface of the bridge chip in the present disclosure are a first metal pillar and a second metal pillar, respectively, and the first metal pillar is connected with a second metal line layer formed in the second redistribution layer by a electroplating process, and the second metal pillar is connected with a first metal line layer formed in the first redistribution layer by a electroplating process, and this way of connecting a metal pillar directly with the metal wiring, compared with the way of connecting with the solder (such as solder tin), the connection strength at the connection point can be guaranteed (without being affected by the curing process), and defects such as voids and/or cracks will not appear, thus improving the reliability of the package structure. The upper insulation layer and the lower insulation layer protect the bridge chip from crack defects in the subsequent package process, and the bridge chip has a symmetrical structure on the front surface and the back surface (with the first metal pillar and the upper insulation layer being on the front surface, and the second metal pillar and the lower insulation layer being on the back surface), which enables the stress on the front surface and the back surface of the bridge chip to be maintained in a balanced manner and prevents the bridge chip from warping or deforming, thus further ensuring the connection strength of the connection point between the first metal pillar and the second metal pillar on the front surface, on the one hand, and the back surface of the bridge chip and the corresponding metal line layer, on the other hand, thereby further improving the reliability of the package structure.

The present disclosure provides, in one aspect, a method for forming a semiconductor package structure, and the process for forming the semiconductor package structure is described in detail below in conjunction with the accompanying drawings.

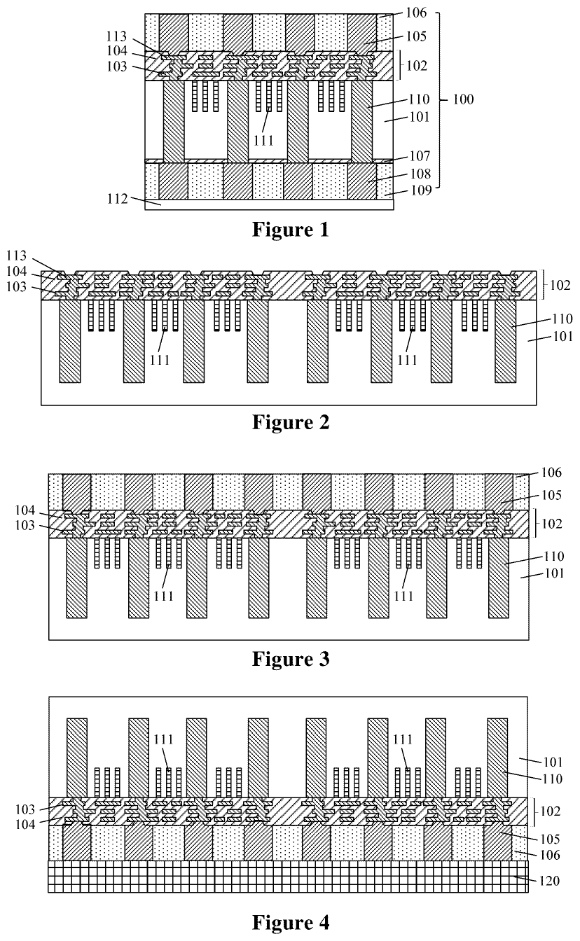

Referring to FIG. 1, a bridge chip 100 is provided, the bridge chip 100 including a substrate 101, the substrate 101 including an opposing front surface and a back surface, the front surface of the substrate 101 having a pad 113, the substrate 101 having in it a through-hole connection structure 110, and the back surface of the substrate 101 exposing a surface of one end of the through-hole connection structure 110; and the bridge chip 100 further includes: a first metal pillar 105 protruding on the front surface of the substrate 101 and electrically connected with the corresponding pad 113; an upper insulation layer 106 covering the first metal pillar 105 and the front surface of the substrate 101; a second metal pillar 108 protruding on the back surface of the substrate 101 and electrically connected with the corresponding through-hole connection structure 110; a lower insulation layer 109 covering the second metal pillar 108 and the back surface of the substrate 101.

The substrate 101 serves as the main body of the bridge chip 100, and in one embodiment, the material of the substrate 101 is silicon (Si). In other embodiments, the material of the substrate 101 may also be germanium (Ge), or silicon-germanium (GeSi), silicon carbide (SiC); it may also be silicon-on-insulator (SOI), germanium-on-insulator (GOI); or it may be other materials, such as III-V compounds such as gallium arsenide.

In one embodiment, the substrate 101 of the bridge chip 100 further has a redistribution layer 102 on the front surface of the substrate 101, the redistribution layer 102 being part of the substrate 101; the pad 113 is located on the upper surface of the redistribution layer 102 and is electrically connected with the redistribution layer 102; and the through-hole connection structure 110 is electrically connected with the redistribution layer 102.

In one embodiment, the redistribution layer 102 includes a passivation layer 104 and a metal line layer 103 located in the passivation layer 104; the passivation layer 104 may be a single-layer or multi-layer stacked structure, and the corresponding metal line layer 103 may be a single-layer or multi-layer stacked structure; the pad 113 is electrically connected with the metal line layer 103. When both the passivation layer 104 and the metal line layer 103 are multi-layer stacked structures, one layer of the passivation layer 104 correspondingly forms in it one layer of the metal line layer. In a specific embodiment, the material of the passivation layer 104 is one or more of silicon oxide, silicon nitride, silicon nitride oxide, silicon carbon oxide, silicon carbon nitride, and the material of the metal line layer 103 is one or more of Al, Cu, Ag, Au, Pt, Ni, Ti, TiN, TaN, Ta, TaC, W, WN.

In one embodiment, a deep trench capacitor 111 is also formed in the substrate 101 of the bridge chip 100, the deep trench capacitor 111 is electrically connected with the redistribution layer 102, and the deep trench capacitor 111 can be used for decoupling and voltage regulation. In other embodiments, there are other functional chips formed in the substrate 101 of the bridge chip 100, which can be used for power management and protection of the battery from damage such as overcharging, overdischarging, overcurrent and the like.

The bridge chip 100 further comprises: a first metal pillar 105 protruding on the front surface of the substrate 101 and electrically connected with corresponding pad 113; an upper insulation layer 106 covering the first metal pillar 105 and the front surface of the substrate 101; a second metal pillar 108 protruding on the back surface of the substrate 101 and electrically connected with corresponding the through-hole connection structure 110; and a lower insulation layer 109 covering the second metal pillar 108 and the back surface of the substrate 101. The connection terminals with the outside of the bridge chip 100 on the front surface and on the back surface of the bridge chip 100 are a first metal pillar 105 and a second metal pillar 108, respectively, the first metal pillar 105 and the second metal pillar 108 being of the same height, the first metal pillar 105 being connected subsequently with a second metal line layer formed in the second redistribution layer by an electroplating process, and the second metal pillar 108 is subsequently connected with the first metal line layer formed in the first redistribution layer by an electroplating process, and this way of directly connecting metal pillars and metal wiring, compared with the way of connecting with solder (e.g., solder tin), the strength of connection at the point of connection can be guaranteed (not being affected by the curing process), and defects such as voids and/or cracks will not appear, thereby improving the reliability of the package structure. The upper insulation layer 106 and the lower insulation layer 109 protect the bridge chip 100 from crack defects in the subsequent package process, and the bridge chip 100 has a symmetrical structure on the front surface and the back surface (the front surface is the first metal pillar 105 and the upper insulation layer 106, and the back surface is the second metal pillar 108 and the lower insulation layer 109), so that the stresses on the front surface and the back surface of the bridge chip 100 can be maintained in balance, preventing the bridge chip 100 from warping or deforming, further ensuring the connection strength at the connection points between the first metal pillar 105 and the second metal pillar 108 on the front surface and the back surface of the bridge chip 100, on the one hand, and the corresponding metal line layer, on the other hand, and thereby further improving the reliability of the package structure.

In one embodiment, with continued reference to FIG. 1, the upper insulation layer 106 exposes the surface of one end of the first metal pillar 105 facing away from the front surface of the substrate 101, and the upper surface of the upper insulation layer 106 is flush with the exposed surface of the first metal pillar 105, the lower insulation layer 109 exposes the surface of one end of the second metal pillar 108 facing away from the back surface of the substrate 101, and the lower surface of the lower insulation layer 109 is flush with this end surface of the first metal pillar 105. In other embodiments, the upper insulation layer 106 may also cover the surface of one end of the first metal pillar 105 facing away from the front surface of the substrate 101, and the lower insulation layer 109 may also cover the surface of one end of the second metal pillar 108 facing away from the back surface of the substrate 101, and when thinning the first plastic sealing layer, the upper insulation layer 106 or the lower insulation layer 109 can be simultaneously thinned to expose the surface of one end of the first metal pillar 105 facing away from the front of the substrate 101 or expose the surface of one end of the second metal pillar 108 facing away from the back surface of the substrate 101.

In one embodiment, the material of the first metal pillar 105 and the second metal pillar 108 is one or more of Al, Cu, Ag, Au, Pt, Ni, Ti, TiN, TaN, Ta, TaC, W, WN. The upper insulation layer 106 and the lower insulation layer 109 are of the same material and may be a molding material or an organic insulation dielectric material. The molding material is an epoxy resin or a resin of other materials, which has a smaller coefficient of thermal expansion and is more conducive to warping management of the bridge chip. The organic insulation dielectric material may be a polymer layer made of polyimide (PI), benzocyclobutene (BCB) or polybenzoxazole (PBO), or a polymer layer made of other suitable polymer-based dielectric materials; the organic insulation dielectric material may also be an epoxy-type adhesive material (such as a Die Attach Film (DAF) or a Non-Conductive Film (NCF)).

In one embodiment, a Die Attach Film (DAF) 112 may also be attached on the surface of the lower insulation layer 109 facing away from the back surface of the substrate 101, to facilitate subsequent bonding of the bridge chip 100 on the first carrier board.

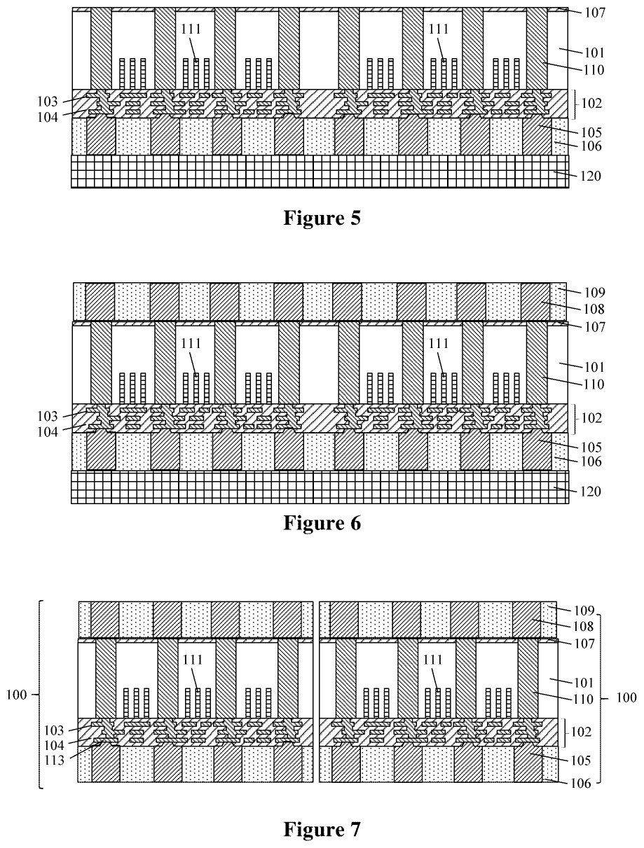

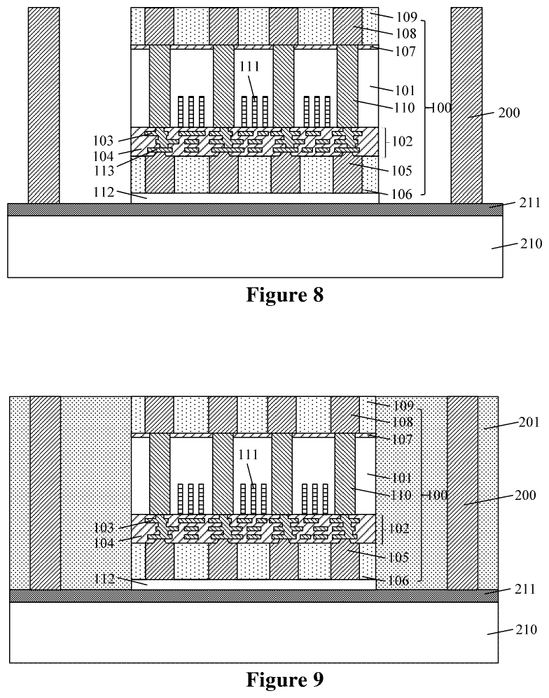

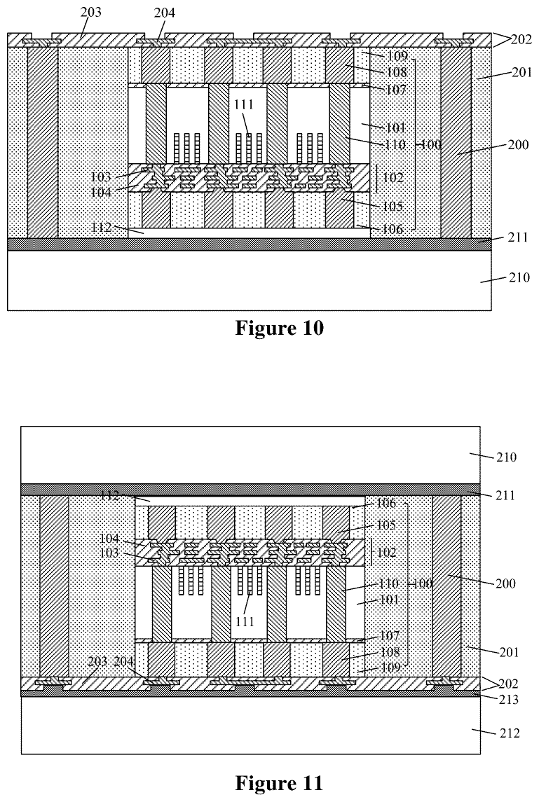

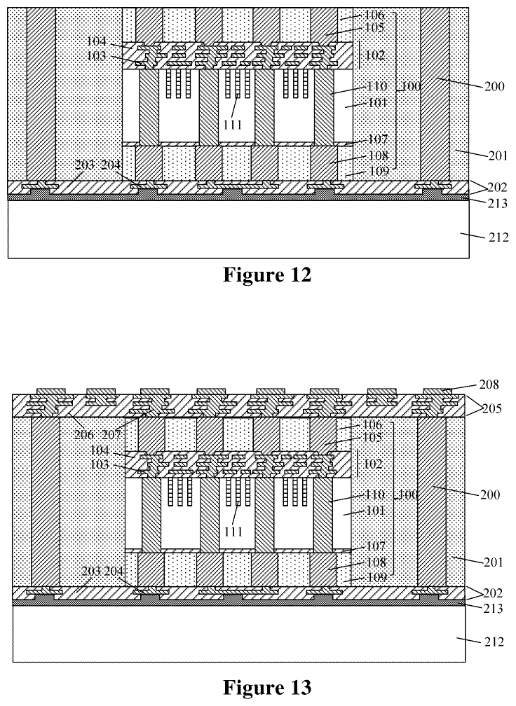

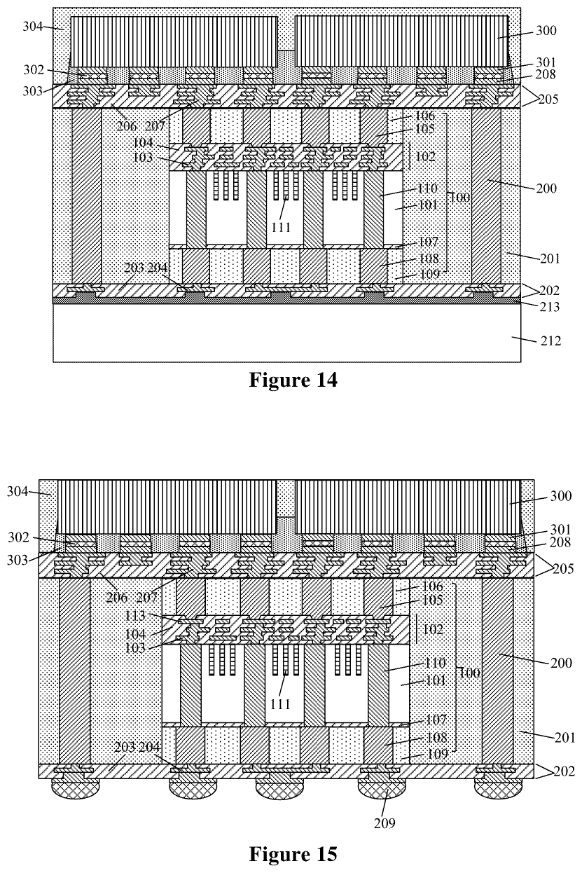

In one embodiment, the process for forming the bridge chip 100 includes: referring to FIG. 2, a substrate 101 is provided, the substrate including a plurality of chip regions and cutting regions located between the chip regions, the same structure is formed subsequently on each of the chip regions; a through-hole connection structure 110 and a deep trench capacitor 111 in the substrate 101 are formed; a redistribution layer 102 is formed on the front surface of the substrate 101, the redistribution layer 102 including a passivation layer 104 and a metal line layer 103 located in the passivation layer 104; a pad 113 is formed on the upper surface of the redistribution layer 102, the pad 113 being electrically connected with the metal line layer 103; with reference to FIG. 3, a protruding first metal pillar 105 is formed on the upper surface of the pad 113, the forming process of the first metal pillar 105 including an electroplating process; an upper insulation layer 106 covering the first metal pillar 105 and the front surface of the substrate 101 is formed, forming the upper insulation layer 106 may be by a spin-coating, injection molding, compression molding, or transfer molding process; referring to FIG. 4, the upper surface of the upper insulation layer 106 is bonded on the surface of a carrier board 120, the bonding may be performed by a temporary bonding layer, the carrier board 120 may be a glass carrier board; referring to FIG. 5, the back surface of the substrate 101 is thinned and etched to expose the surface of one end of the through-hole connection structure 110, and the process of thinning and etching includes: at first, the substrate 101 is thinned to a certain height, then a chemical-mechanical grinding process is performed to remove a part of the substrate, and then an etching process is performed to continue to remove a part of the substrate until the surface of one end of the through-hole connection structure 110 is exposed, and the surface of one end of the through-hole connection structure 110 is higher than the surface of the substrate 101; a second passivation layer 107 of a certain thickness is formed on the back surface of the etched substrate 101, and a chemical mechanical grinding process is performed to remove a part of the protruding through-hole connection structure 110, the surface of the second passivation layer 107 is flush with the exposed surface of one end of the through-hole connection structure 110, and the material of the second passivation layer 107 may be one or more of silicon oxide, silicon nitride, silicon nitride oxide, silicon carbon oxide, silicon carbon-nitride; and with reference to FIG. 6, a protruding second metal pillar 108 is formed on the exposed surface of the through-hole connection structure 110, the process for forming the second metal pillar 108 including an electroplating process, and the diameter size of the second metal pillar 108 is larger than the diameter size of the through-hole connection structure 110, which not only improves the connection quality between the second metal pillar and the through-hole connection structure, but also facilitates the dissipation of heat during the subsequent operation of the bridge chip; a lower insulation layer 109 covering the second metal pillar 108 and the back surface of the substrate 101 is formed, and the formation of the lower insulation layer 109 may be performed by a spin-coating, injection molding, compression molding, or transfer molding process; referring to FIG. 7, the substrate 101 is cut along the cutting area to form a number of discrete bridge chips 100. By adopting a semiconductor integration manufacturing process, the processing efficiency of the bridge chip 100 is improved.

Referring to FIG. 8, a first carrier board 210 is provided, and an upper insulation layer 106 of the bridge chip 100 is bonded on an upper surface of the first carrier board 210.

The first carrier board 210 supports and protects the bridge chip 100 during subsequent package. In one embodiment, the first carrier board 210 is a glass carrier board.

In one embodiment, an upper insulation layer 106 of the bridge chip 100 is bonded on the upper surface of the first carrier board 210 by means of a temporary bonding layer 211. The temporary bonding layer 211 may be a temporary bonding adhesive and a multi-layer metal layer structure such as Al/Ti/Cu.

In one embodiment, the first carrier board 210 may have a plurality of package regions, the same structure is formed subsequently on each package region, e.g., when a bridge chip 100 is bonded on the upper surface of the first carrier board 210, the same bridge chip 100 is bonded on the upper surface of each package region of the first carrier board 210. The number of bridge chips 100 bonded on the upper surface of each package area of the first carrier board 210 is at least one.

In one embodiment, it further includes: a columnar connection structure 200 is formed on the upper surface of the first carrier board 210 on one or more sides of the bridge chip 100 prior to the subsequent formation of the first molded package layer. The columnar connection structure 200 is used for electrical connection between the first redistribution layer and the second redistribution layer in the subsequently formed package structure. The material of the columnar connection structure 200 is a metal, and the material of the columnar connection structure 200 may specifically be one or more of Al, Cu, Ag, Au, Pt, Ni, Ti, TiN, TaN, Ta, TaC, W, WN, and the process for forming the columnar connection structure 200 includes electroplating.

Referring to FIG. 9, a first molding layer 201 covering the upper surface of the first carrier board 210 and the bridge chip 100 is formed.

In one embodiment, the material of the first molding layer 201 may be a filler-containing epoxy resin, a polyimide resin, a benzocyclobutene resin, or a polybenzoxazole resin; or it may also be a filler-containing polybutylene terephthalate, polycarbonate, polyethylene terephthalate, polyethylene, polypropylene, polyolefin, polyurethane, polyolefin, polyethersulfone, polyamide, polyimide, ethylene-vinyl acetate copolymer, or polyvinyl alcohol. In some embodiments, the filler may be an inorganic filler or an organic filler. In some embodiments, the process for forming the molding layer includes a compression molding process or a transfer molding process.

In one embodiment, the first molding layer 201 further covers the columnar connection structure 200.

Referring to FIG. 10, a surface of the first molding layer 201 facing away from the first carrier board is thinned, a surface of one end of the second metal pillar 108 facing away from the back surface of the substrate 101 is exposed; a first redistribution layer 202 is formed on the surface of the thinned first molding layer 201, the first redistribution layer 202 being electrically connected with the second metal pillar 108, and the process for forming the first redistribution layer 202 includes an electroplating process.

In one embodiment, when the lower insulation layer 109 in the bridge chip 100 exposes a surface of one end of the second metal pillar 108 facing away from the back surface of the substrate 101 and the lower surface of the lower insulation layer 109 is flush with that end surface of the first metal pillar 105, after the surface of the first molding layer 201 facing away from the first carrier board is thinned, a surface of the second metal pillar 108 and the lower insulation layer 109 facing away from the back surface of the substrate 101 are exposed. In other embodiments, the lower insulation layer 109 may also cover the surface of one end of the second metal pillar 108 facing away from the back surface of the substrate 101, and when the surface of the first molding layer 201 facing away from the first carrier board is thinned, the surface of the lower insulation layer 109 facing away from the back surface of the substrate 101 can be simultaneously thinned to expose the surface of one end of the second metal pillar 108 facing away from the back surface of the substrate 101.

In one embodiment, thinning the first molding layer 201 (and the lower insulation layer 109) includes a chemical mechanical grinding process.

In one embodiment, the first redistribution layer 202 is further electrically connected with the columnar connection structure 200.

In one embodiment, the first redistribution layer 202 includes a first organic dielectric layer 203 and a first metal line layer 204 located in the first organic dielectric layer 203; the first organic dielectric layer 203 is a single-layer or multi-layer stacked structure, and the corresponding first metal line layer 204 is a single-layer or multi-layer stacked structure. When both the first organic dielectric layer 203 and the first metal line layer 204 are multi-layer stacked structures, each layer of the first organic dielectric layer 203 correspondingly has in it a layer of the first metal line layer 204, and the first metal line layer 204 of the upper layer is electrically connected with the first metal line layer 204 of the adjacent lower layer.

In a specific example, the material of the first organic dielectric layer 203 may be a polymer layer made of polyimide (PI), benzocyclobutene (BCB) or polybenzoxazole (PBO), or other suitable polymer-based dielectric material. The material of the first metal line layer 204 is one or more of Al, Cu, Ag, Au, Pt, Ni, Ti, TiN, TaN, Ta, TaC, W, WN.

In one embodiment, when the first organic dielectric layer 203 and the first metal line layer 204 are both one layer, the process for forming the first redistribution layer 202 includes: a first organic dielectric layer 203 is formed on the surface of the thinned first molding layer 201 and lower insulation layer 109 using a coating process; an exposure process, a development process and a thermal curing process are performed on the first organic dielectric layer 203 formed by coating, a first opening exposing the surface of one end of the second metal pillar 108 is formed in the first organic dielectric layer 203; a seed layer is formed on the upper surface of the first organic dielectric layer 203 and on the sidewalls of the first opening and on the bottom surface of the first opening; a photoresist layer is formed on the upper surface of the seed layer; the photoresist layer is patterned, a second opening in the photoresist layer that exposes the seed layer in the first opening and a portion of the surface of the seed layer outside the first opening is formed; a first metal line layer 204 is formed in the second opening using an electroplating process; and the photoresist layer is removed. When both the first organic dielectric layer 203 and the first metal line layer 204 are multi-layer stacked structures, the aforementioned steps of forming the first organic dielectric layer 203 and the first metal line layer 204 are repeated. The first metal line layer 204 formed in the first redistribution layer by the electroplating process is connected with the second metal pillar 108, and this way of direct connection of the metal pillar and the metal wiring, compared with the way of connection by solder (such as solder tin), the strength of connection at the point of connection can be guaranteed (not affected by the curing process), and there will be no defects such as voids and/or cracks, which improves the reliability of the package structure.

In one embodiment, the first redistribution layer 202 being electrically connected with the second metal pillar 108 includes: the first metal line layer 204 being electrically connected with the second metal pillar 108.

In one embodiment, the first redistribution layer 202 has in it openings exposing a portion of the surface of the first metal line layer 204 to allow for subsequent formation of solder bumps electrically connected with the first redistribution layer 202.

Referring to FIG. 11, a second carrier board 212 is provided, the first redistribution layer 202 is bonded on the upper surface of the second carrier board 212.

In one embodiment, the first redistribution layer 202 is bonded on the upper surface of the second carrier board 212 by a temporary bonding layer 211. The temporary bonding layer 211 may be a combination of a temporary bonding adhesive, a metal barrier layer, and a delamination layer, or it may be a pyrolytic bonding adhesive.

Referring to FIG. 12, the first carrier board 210 is removed to expose the upper insulation layer 106; the surface of the first molding layer 201 facing away from the second carrier board 212 is thinned to expose the surface of one end of the first metal pillar 105 facing away from the front surface of the substrate 101.

In one embodiment, when the upper insulation layer 106 in the bridge chip 100 exposes the surface of one end of the first metal pillar 105 facing away from the front surface of the substrate 101 and the upper surface of the upper insulation layer 106 is flush with the exposed surface of the first metal pillar 105, the surface of the first molding layer 201 facing away from the second carrier board 212 is thinned to expose the first metal pillar 105 and the surface of the upper insulation layer 106 facing away from the substrate 101. In other embodiments, the upper insulation layer 106 may also cover the surface of one end of the first metal pillar 105 facing away from the front surface of the substrate 101, and when the surface of the first molding layer 201 facing away from the surface of the second carrier board 212 is thinned, the surface of the upper insulation layer 106 facing away from the front surface of the substrate 101 can be simultaneously thinned to expose the surface of one end of the first metal pillar 105 facing away from the front surface of the substrate 101.

Thinning of the first molding layer 201 (and upper insulation layer 106) includes a chemical mechanical grinding process.

In one embodiment, after eliminating or reducing the adhesion of the delamination layer in the temporary bonding layer 211 by laser or heat, the first carrier board is removed, and then the metal barrier layer and the temporary bonding adhesive are removed.

In one embodiment, while the thinning of the upper insulation layer 106 and the first molding layer 201 is performed, the columnar connection structure 200 is also thinned.

Referring to FIG. 13, a second redistribution layer 205 is formed on the surface of the thinned first molding layer 201, the second redistribution layer 205 being electrically connected with the first metal pillar 105, and the process for forming the second redistribution layer 205 includes an electroplating process.

In one embodiment, the second redistribution layer 205 includes a second organic dielectric layer 206 and a second metal line layer 207 located in the second organic dielectric layer 206; the second organic dielectric layer 206 is a single-layer or multi-layer stacked structure, and the corresponding second metal line layer 207 is a single-layer or multi-layer stacked structure; the second redistribution layer 205 further includes micro pads 208 located on the upper surface of the second organic dielectric layer 206 on the top layer and electrically connected with the second metal line layer 207. When the second organic dielectric layer 206 and the second metal line layer 207 are both multi-layer stacked structures, each layer of the second organic dielectric layer 206 correspondingly has in it a layer of the second metal line layer 207, and the second metal line layer 207 of the upper layer is electrically connected with the second metal line layer 207 of the adjacent lower layer.

In one embodiment, the second redistribution layer 205 being electrically connected with the first metal pillar 105 includes: the second metal line layer 207 being electrically connected with the first metal pillar 105.

In a specific embodiment, the material of the second organic dielectric layer 206 may be a polymer layer made of polyimide (PI), benzocyclobutene (BCB) or polybenzoxazole (PBO), or other suitable polymer-based dielectric material. The material of the second metal line layer 207 and micro pads 208 is one or more of Al, Cu, Ag, Au, Pt, Ni, Ti, TiN, TaN, Ta, TaC, W, WN.

In one embodiment, when the second organic dielectric layer 206 and the second metal line layer 207 are both one layer, the process for forming the second redistribution layer 205 includes: a second organic dielectric layer 206 is formed on the surface of the thinned upper insulation layer 106 and the first molding layer 201 by using a coating process; an exposure process, a development process and a thermal curing process are performed on the first organic dielectric layer 203 formed by coating, a third opening exposing the surface of one end of the second metal pillar 108 is formed in the first organic dielectric layer 203; a seed layer is formed on the upper surface of the first organic dielectric layer 203 and on the sidewalls of the third opening and on the bottom surface of the third opening; a photoresist layer is formed on the upper surface of the seed layer; the photoresist layer is patterned, a fourth opening in the photoresist layer that exposes the seed layer in the third opening and a portion of the surface of the seed layer outside the third opening is formed; a second metal line layer 207 is formed in the fourth opening using an electroplating process; and the photoresist layer is removed. When both the second organic dielectric layer 206 and second metal line layer 207 are multi-layer stacked structures, the aforementioned steps of forming the second organic dielectric layer 206 and second metal line layer 207 are repeated. The second metal line layer 207 formed in the second redistribution layer 205 by the electroplating process is connected with the second metal pillar 108, and this way of direct connection of the metal pillar and the metal wiring, compared with the way of connection by solder (such as solder tin), the strength of connection at the point of connection can be guaranteed (not affected by the curing process), and there will be no defects such as voids and/or cracks, which improves the reliability of the package structure.

In one embodiment, the second redistribution layer 205 is further electrically connected with the columnar connection structure 200. The second redistribution layer 205 being further electrically connected with the columnar connection structure 200 including: the second metal line layer 207 being electrically connected with the columnar connection structure 200.

Referring to FIG. 14, a semiconductor chip 300 is provided, and the semiconductor chip 300 is mounted on the upper surface of the second redistribution layer 205, the semiconductor chip 300 being electrically connected with the second redistribution layer 205; and a second molding layer 304 covering the upper surface of the second redistribution layer 205 and the semiconductor chip 300 is formed.

The semiconductor chip 300 includes an opposing back surface and an active surface, the semiconductor chip 300 having in it an integrated circuit (with a specific function, not shown in the figures) being formed, the active surface having a plurality of micro bumps 301 on it, the plurality of the micro bumps 301 being electrically connected with the integrated circuit. In one embodiment, the semiconductor chip 300 is mounted on the upper surface of the second redistribution layer 205, the semiconductor chip 300 being electrically connected with the second redistribution layer 205 includes: the micro bumps 301 on the semiconductor chip 300 being soldered with the micro pads 208 by means of solder layer 302. In a specific embodiment, the material of the micro bumps 301 is one or more of aluminum, nickel, tin, tungsten, platinum, copper, titanium, chromium, tantalum, gold, and silver, and the material of the solder layer 302 is one or more of tin, tin-silver, tin-lead, tin-silver-copper, tin-silver-zinc, tin-zinc, tin-bismuth-indium, tin-indium, tin-gold, tin-copper, tin-zinc-indium, or tin-silver-antimony.

The semiconductor chip 300 includes, but is not limited to, a signal processing semiconductor chip, a logic control semiconductor chip, a storage semiconductor chip, a sensor semiconductor chip, a power semiconductor chip, or a radio frequency semiconductor chip, depending on the function.

In one embodiment, the number of the mounted semiconductor chips 300 is one or more, and an underfill layer 303 is also filled between the semiconductor chips 300 and the upper surface of the second redistribution layer 205.

In one embodiment, the material of the second molding layer 304 may be a filler-containing epoxy resin, polyimide resin, benzocyclobutene resin, or polybenzoxazole resin; or it may also be a filler-containing polybutylene terephthalate, polycarbonate, polyethylene terephthalate, polyethylene, polypropylene, polyolefin, polyurethane, polyolefin, polyethersulfone, polyamide, polyurethane, ethylene-vinyl acetate copolymer, or polyvinyl alcohol. In some embodiments, the filler may be an inorganic filler or an organic filler. In some embodiments, the process for forming the molding layer comprises a compression molding process or a transfer molding process.

In one embodiment, referring to FIG. 15, it further includes: the second carrier board 212 is removed to expose the first redistribution layer 202; a solder bump 209 electrically connected with the first redistribution layer 202 is formed on the lower surface of the first redistribution layer 202.

In one embodiment, the solder bump 209 also has a convex lower metal layer at the bottom. The material of the convex lower metal layer is one or more of aluminum, nickel, tin, tungsten, platinum, copper, titanium, chromium, tantalum, gold, and silver. The material of the solder bump 209 is one or more of tin, tin-silver, tin-lead, tin-silver-copper, tin-silver-zinc, tin-zinc, tin-bismuth-indium, tin-indium, tin-gold, tin-copper, tin-zinc-indium, or tin-silver-antimony

In one embodiment, after forming the solder bump 209, it further includes: the second molding layer 304 is thinned to expose the back surface of the semiconductor chip 300.

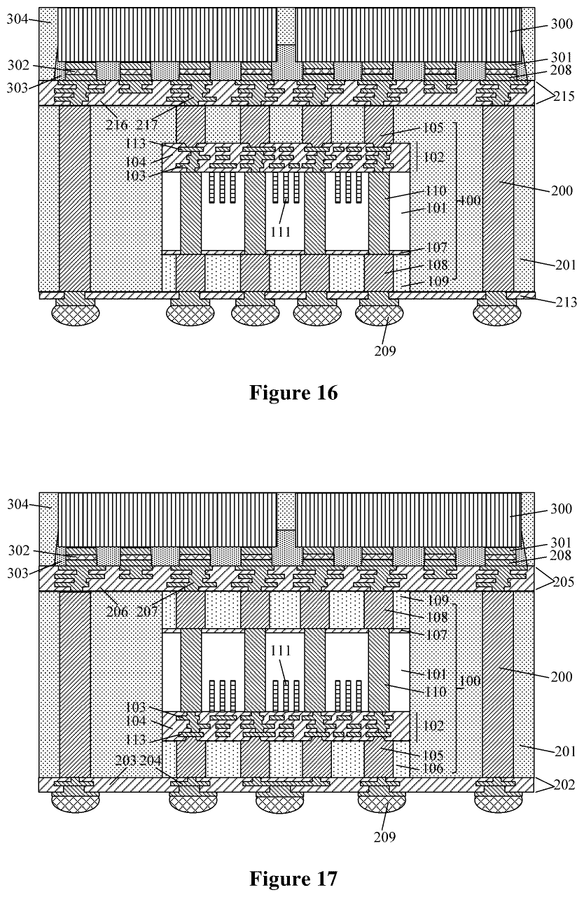

A method for forming a semiconductor package structure is also provided in another embodiment of the present disclosure (the difference between this embodiment and the aforementioned embodiments is that: an upper insulation layer covering the first metal pillars will be formed on the front surface of the bridge chip, the space between the first metal pillars is filled by the first molding layer during the process, a redistribution layer will not be formed on the back surface of the package structure, and the second metal pillars are directly electrically connected with the solder bumps, in addition to the benefits of the aforementioned embodiments, the process flow time of the bridge chip can be saved), specifically, referring to FIG. 16, including:

a bridge chip 100 is provided, the bridge chip 100 including a substrate 101, the substrate 101 including opposed front surface and back surface, the front surface of the substrate 101 having a pad 113, the substrate 101 having in it a through-hole connection structure 110, and the back surface of the substrate 101 exposes a surface of an end of the through-hole connection structure 110; the bridge chip 100 further includes: a first metal pillar 105 protruding on the front surface of the substrate 101 and electrically connected with the corresponding pad 113; a second metal pillar 108 protruding on the back surface of the substrate 101 and electrically connected with the corresponding through-hole connection structure 110; and a lower insulation layer 109 covering the second metal pillar 108 and the back surface of the substrate 101; a carrier board (not shown in the figures) is provided, and the lower insulation layer 109 of the bridge chip is bonded on the upper surface of the carrier board; a first molding layer 201 covering the upper surface of the carrier board and the bridge chip 100 is formed, and filled between the first metal pillars 105; a surface of the first molding layer 201 facing away from the carrier board is thinned, and the surface of one end of the first metal pillar 105 facing away from the front surface of the substrate 101 is exposed; an upper redistribution layer 215 is formed on the surface of the thinned first molding layer 201, the upper redistribution layer 215 being electrically connected with the first metal pillar 105, the process for forming the upper redistribution layer 215 including an electroplating process; a semiconductor chip 300 is provided, the semiconductor chip 300 is mounted on the upper surface of the upper redistribution layer 215, the semiconductor chip 300 being electrically connected with the upper redistribution layer 215; a second molding layer 304 covering the upper surface of the upper redistribution layer 215 and the semiconductor chip 300 is formed; the carrier board is removed to expose the lower insulation layer 109; and a solder bump 209 electrically connected with the second metal pillar 108 is formed on the lower insulation layer 109.

In one embodiment, the substrate 101 of the bridge chip 100 further has a redistribution layer 102 on the front surface of the substrate 101, the redistribution layer 102 being a part of the substrate 101; and the pad 113 is located on the upper surface of the redistribution layer 102 and electrically connected with the redistribution layer 102; and the through-hole connection structure 110 is electrically connected with the redistribution layer 102. In one embodiment, the redistribution layer 102 includes a passivation layer 104 and a metal line layer 103 located in the passivation layer 104; the passivation layer 104 may be a single-layer or multi-layer stacked structure, and the corresponding metal line layer 103 may be a single-layer or multi-layer stacked structure; the pad 113 is electrically connected with the metal line layer 103.

The structure of the upper redistribution layer 215 is essentially the same as the structure of the second redistribution layer in the aforementioned embodiment. In a specific embodiment, the upper redistribution layer 215 includes a third organic dielectric layer 216 and a third metal line layer 217 located in the third organic dielectric layer 216; the third organic dielectric layer 216 is a single-layer or multi-layer stacked structure, and the corresponding third metal line layer 217 is a single-layer or multi-layer stacked structure. When both the third organic dielectric layer 216 and the third metal line layer 217 are multi-layer stacked structures, each layer of the third organic dielectric layer 216 correspondingly has in it a layer of the third metal line layer 217, and the third metal line layer 217 of the upper layer is electrically connected with the third metal line layer 217 of the adjacent lower layer.

In one embodiment, before forming the solder bump 209 electrically connected with the second metal pillar 108 on the lower insulation layer 109, a lower organic dielectric layer 213 can also be formed on the surface of the lower insulation layer 109, and the lower organic dielectric layer 213 has in it an opening exposing the surface of the second metal pillar 108; a convex lower metal layer is formed in the openings; and the solder bump 209 is formed on the convex lower metal layer.

In another aspect, the present disclosure also provides a semiconductor package structure, referring to FIG. 15, including: a bridge chip 100, the bridge chip 100 including a substrate 101, the substrate 101 including opposed front surface and back surface, the front surface of the substrate 101 having a pad 113, the substrate 101 having in it a through-hole connection structure 110, the back surface of the substrate 101 exposing a surface of one end of the through-hole connection structure 110; and the bridge chip 100 further includes: a first metal pillar 105 protruding on the front surface of the substrate 101 and electrically connected with the corresponding pad 113; an upper insulation layer 106 covering the first metal pillar 105 and the front surface of the substrate 101, an upper surface of the upper insulation layer 106 exposing the surface of an end of the first metal pillar 105 facing away from the front surface of the substrate 101; a second metal pillar 108 protruding on the back surface of the substrate 101 and electrically connected with the corresponding through-hole connection structure 110; a lower insulation layer 109 covering the second metal pillar 108 and the back surface of the substrate 101, the lower surface of the lower insulation layer 109 exposing the surface of one end of the second metal pillar 108 facing away from the back surface of the substrate 101; a first molding layer 201 covering the bridge chip 100, the upper surface of the first molding layer 201 exposing the upper surface of the upper insulation layer 106 and the surface of one end of the first metal pillar 105 facing away from the front surface of the substrate 101, the lower surface of the first molding layer 201 exposing the lower surface of the lower insulation layer 109 and the surface of one end of the second metal pillar 108 facing away from the back surface of the substrate 101; a first redistribution layer 202 located on the lower surface of the first molding layer 201 and the lower insulation layer 109, the first redistribution layer 202 being electrically connected with the second metal pillar 108; a second redistribution layer 205 located on the upper surface of the first molding layer 201 and the upper insulation layer 106, the second redistribution layer 205 being electrically connected with the first metal pillar 105; a semiconductor chip 300, the semiconductor chip 300 being mounted on the upper surface of the second redistribution layer 205, the semiconductor chip 300 being electrically connected with the second redistribution layer 205; and a second molding layer 304 covering the upper surface of the second redistribution layer 205 and the semiconductor chip 300.

In one embodiment, the first redistribution layer 202 includes a first organic dielectric layer 203 and a first metal line layer 204 located in the first organic dielectric layer 203; the first organic dielectric layer 203 is a single-layer or multi-layer stacked structure, and the corresponding first metal line layer 204 is a single-layer or multi-layer stacked structure; the first redistribution layer 202 being electrically connected with the second metal pillar 108 including: the first metal line layer 204 being electrically connected with the second metal pillar 108.

In one embodiment, the second redistribution layer 205 includes a second organic dielectric layer 206 and a second metal line layer 207 located in the second organic dielectric layer 206; the second organic dielectric layer 206 is a single-layer or multi-layer stacked structure, and the corresponding second metal line layer 207 is a single-layer or multi-layer stacked structure; the second redistribution layer 205 further includes micro pads 208 located on the upper surface of the second organic dielectric layer 206 on the top layer and electrically connected with the second metal line layer 207.

In one embodiment, the semiconductor chip 300 is mounted on the upper surface of the second redistribution layer 205, the semiconductor chip 300 being electrically connected with the second redistribution layer 205 includes: micro bumps 301 on the semiconductor chip 300 being soldered together with the micro pads 208 by solder layer 302; the second redistribution layer 205 being electrically connected with the first metal pillar 105 including: the second metal line layer 207 being electrically connected with the first metal pillar 105.

In one embodiment, it further includes: a columnar connection structure 200 located on one side or more sides of the bridge chip 100; the first molding layer 201 further covering the columnar connection structure 200; the first redistribution layer 202 and the second redistribution layer 205 being further electrically connected with the columnar connection structure 200.

In one embodiment, the substrate 101 of the bridge chip 100 further has a redistribution layer 102 on the front surface of the substrate 101, the redistribution layer 102 is a part of the substrate 101; the pad 113 is located on the upper surface of the redistribution layer 102 and is electrically connected with the redistribution layer 102; and the through-hole connection structure 110 is electrically connected with the redistribution layer 102.

In one embodiment, the redistribution layer 102 includes a passivation layer 104 and a metal line layer 103 located in the passivation layer 104; the passivation layer 104 is a single-layer or multi-layer stacked structure, and the corresponding metal line layer 103 is a single-layer or multi-layer stacked structure; and the pad 113 is electrically connected with the metal line layer 103.

In one embodiment, a deep trench capacitor 111 is also formed in the substrate 101 of the bridge chip 100, the deep trench capacitor 111 being electrically connected with the redistribution layer 102.

In one embodiment, the material of the upper insulation layer 106 and the lower insulation layer 109 is a molding material or an organic insulation dielectric material.

Another embodiment of the present disclosure also provides a semiconductor package structure, the difference between this embodiment and the aforementioned embodiments is that: an upper insulation layer covering the first metal pillars is not formed on the front surface of the bridge chip, the first molding layer is filled between the first metal pillars, a redistribution layer is not formed on the back surface of the package structure, and the second metal pillars are directly electrically connected with the solder bumps, and specifically, with reference to FIG. 16, including: a bridge chip 100, the bridge chip 100 including a substrate 101, the substrate 101 including opposed front surface and back surface, the front surface of the substrate 101 having a pad 113, the substrate 101 having in it a through-hole connection structure 110, the back surface of the substrate 101 exposing a surface of one end of the through-hole connection structure 110; the bridge chip 100 further including: a first metal pillar 105 protruding on the front surface of the substrate 101 and electrically connected with the corresponding pad 113; a second metal pillar 108 protruding on the back surface of the substrate 101 and electrically connected with the corresponding through-hole connection structure 110; and a lower insulation layer 109 covering the second metal pillar 108 and the back surface of the substrate 101; a first molding layer 201 covering the bridge chip 100 and filling between the first metal pillars 105, an upper surface of the first molding layer 201 exposing the surface of an end of the first metal pillars 105 facing away from the front surface of the substrate 101, and a lower surface of the first molding layer 201 exposing the surface of an end of the second metal pillars 108 facing away from the back surface of the substrate 101; an upper redistribution layer 215 located on the upper surface of the first molding layer 201, the upper redistribution layer 215 being electrically connected with the first metal pillar 105; a semiconductor chip 300, the semiconductor chip 300 being mounted on the upper surface of the upper redistribution layer 215, the semiconductor chip 300 being electrically connected with the upper redistribution layer 215; a second molding layer 304 covering the upper surface of the upper redistribution layer 215 and the semiconductor chip 300; and a solder bump 209 located on the lower insulation layer 109 and electrically connected with the second metal pillar 108.

Yet another embodiment of the present disclosure also provides a semiconductor package structure, the difference between this embodiment and the aforementioned embodiments is that: the first metal pillar of the bridge chip is packaged downward during the formation of the semiconductor package structure to meet different package needs, specifically, with reference to FIG. 17, including: a bridge chip 100, the bridge chip 100 including a substrate 101, the substrate 101 including opposed front surface and back surface, the front surface of the substrate 101 having a pad 113, the substrate 101 having in it a through-hole connection structure 110, the back surface of the substrate 101 exposing a surface of one end of the through-hole connection structure 110; the bridge chip 100 further includes: a first metal pillar 105 protruding on the front surface of the substrate 101 and electrically connected with the corresponding pad 113; an upper insulation layer 106 covering the first metal pillar 105 and the front surface of the substrate 101; a second metal pillar 108 protruding on the back surface of the substrate 101 and electrically connected with the through-hole connection structure 110; a lower insulation layer 109 covering the second metal pillar 108 and the back surface of the substrate 101; a first molding layer 201 covering the bridge chip 100, the upper surface of the first molding layer 201 exposing the surface of one end of the second metal pillar 108 facing away from the back surface of the substrate 101, and the lower surface of the first molding layer 201 exposing the surface of one end of the first metal pillar 105 facing away from the front surface of the substrate 101; a first redistribution layer 202 located on the lower surface of the first molding layer 201 and the upper insulation layer 106, the first redistribution layer 202 being electrically connected with the first metal pillar 105; a second redistribution layer 205 located on the upper surface of the first molding layer 201 and the lower insulation layer 109, the second redistribution layer 205 being electrically connected with the second metal pillar 108; a semiconductor chip 300, the semiconductor chip 300 being mounted on the upper surface of the second redistribution layer 205, the semiconductor chip 300 being electrically connected with the second redistribution layer 205; a second molding layer 304 covering the upper surface of the second redistribution layer 205 and the semiconductor chip 300; and a solder bump 209 located on the lower surface of the first redistribution layer 202 and electrically connected with the first redistribution layer 202.

Although the present disclosure has been disclosed as above with some embodiments, it is not intended to limit the present disclosure, and any person skilled in the art may, without departing from the spirit and scope of the present disclosure, make possible changes and modifications to the technical solutions of the present disclosure by utilizing the above disclosed methods and technical contents, therefore, any simple modifications, equivalent changes, and modifications made to the above embodiments based on the technical substance of the present disclosure without departing from the content of the technical solutions of the present disclosure are within the scope of protection of the technical solutions of the present disclosure.

What is claimed is:

1. A semiconductor package structure, comprising:
a bridge chip, the bridge chip comprising a substrate, the substrate comprising opposed front surface and back surface, the front surface of the substrate having a pad, the substrate having a through-hole connection structure, the back surface of the substrate exposing a surface of one end of the through-hole connection structure, the bridge chip further comprises:
a first metal pillar protruding on the front surface of the substrate and electrically connected with the corresponding pad;
an upper insulation layer covering the first metal pillar and the front surface of the substrate, an upper surface of the upper insulation layer exposing a surface of one end of the first metal pillar facing away from the front surface of the substrate;
a second structure; and
a lower insulation layer covering the second metal pillar and the back surface of the substrate, a lower surface of the lower insulation layer exposing a surface of one end of the second metal pillar facing away from the back surface of the substrate;
a first molding layer covering the bridge chip, the upper surface of the first molding layer exposing the upper surface of the upper insulation layer and the surface of one end of the first metal pillar facing away from the front surface of the substrate, the lower surface of the first molding layer exposing the lower surface of the lower insulation layer and the surface of one end of the second metal pillar facing away from the back surface of the substrate;
a first redistribution layer located on the lower surface of the first molding layer and the lower insulation layer, the first redistribution layer being electrically connected with the second metal pillar;
a second redistribution layer located on the upper surface of the first molding layer and the upper insulation layer, the second redistribution layer being electrically connected with the first metal pillar;
a semiconductor chip, the semiconductor chip being mounted on the upper surface of the second redistribution layer, the semiconductor chip being electrically connected with the second redistribution layer; and
a second molding layer covering the upper surface of the second redistribution layer and the semiconductor chip.

2. The semiconductor package structure according to claim 1, wherein heights of the first metal pillar and the second metal pillar are the same.

3. The semiconductor package structure according to claim 1, wherein materials of the upper insulation layer and the lower insulation layer are the same.

4. The semiconductor package structure according to claim 1, wherein
the first redistribution layer comprises a first organic dielectric layer and a first metal line layer located in the first organic dielectric layer;
the first organic dielectric layer is a single-layer or multi-layer stacked structure, and the corresponding first metal line layer is a single-layer or multi-layer stacked structure; and
the first redistribution layer is electrically connected with the second metal pillar by the first metal line layer being electrically connected with the second metal pillar.

5. The semiconductor package structure according to claim 1, wherein
the second redistribution layer comprises a second organic dielectric layer and a second metal line layer located in the second organic dielectric layer;
the second organic dielectric layer is a single-layer or multi-layer stacked structure, and the corresponding second metal line layer is a single-layer or multi-layer stacked structure; and
the second redistribution layer further comprises micro pads located on the upper surface of the second organic dielectric layer on a top layer and electrically connected with the second metal line layer.

6. The semiconductor package structure according to claim 5, wherein
the semiconductor chip is mounted on the upper surface of the second redistribution layer;
the semiconductor chip is electrically connected with the second redistribution layer by micro bumps on the semiconductor chip being soldered together with the micro pads; and
the second redistribution layer is electrically connected with the first metal pillar by the second metal line layer being electrically connected with the first metal pillar.

7. The semiconductor package structure according to claim 1, wherein
the substrate of the bridge chip further has a redistribution layer on a front surface of the substrate, the redistribution layer being a part of the substrate; and
the pads are located on the upper surface of the redistribution layer and electrically connected with the redistribution layer; and the through-hole connection structure is electrically connected with the redistribution layer.

8. The semiconductor package structure according to claim 7, wherein
the redistribution layer comprises a passivation layer and a metal line layer located in the passivation layer;
the passivation layer is a single-layer or multi-layer stacked structure, and the corresponding metal line layer is a single-layer or multi-layer stacked structure; and
the pads are electrically connected with the metal line layer.

9. The semiconductor package structure according to claim 1, wherein an underfill layer is further filled between the semiconductor chip and the upper surface of the second redistribution layer.

10. The semiconductor package structure according to claim 1, wherein a deep trench capacitor is further formed in the substrate of the bridge chip, the deep trench capacitor being electrically connected with the redistribution layer.

11. A semiconductor package structure, comprising:
a bridge chip, the bridge chip comprising a substrate, the substrate comprising opposed front surface and back surface, the front surface of the substrate having a pad, the substrate having a through-hole connection structure, the back surface of the substrate exposing a surface of one end of the through-hole connection structure, the bridge chip further comprises:
a first metal pillar protruding on the front surface of the substrate and electrically connected with the corresponding pad;
a second metal pillar protruding on the back surface of the substrate and electrically connected with the corresponding through-hole connection structure; and
a lower insulation layer covering the second metal pillar and the back surface of the substrate;
a first molding layer covering the bridge chip and filling between the first metal pillars, an upper surface of the first molding layer exposing the surface of one end of the first metal pillar facing away from the front surface of the substrate, the lower surface of the first molding layer exposing the surface of one end of the second metal pillar facing away from the back surface of the substrate;
an upper redistribution layer located on the upper surface of the first molding layer, the upper redistribution layer being electrically connected with the first metal pillar;
a semiconductor chip, the semiconductor chip being mounted on an upper surface of the upper redistribution layer, the semiconductor chip being electrically connected with the upper redistribution layer;
a second molding layer covering the upper surface of the upper redistribution layer and the semiconductor chip; and
a solder bump located on the lower insulation layer and electrically connected with the second metal pillar.

12. The semiconductor package structure according to claim 11, wherein heights of the first metal pillar and the second metal pillar are the same.

13. The semiconductor package structure according to claim 11, wherein
the substrate of the bridge chip further has a redistribution layer on a front surface of the substrate, the redistribution layer being a part of the substrate; and
the pads are located on an upper surface of the redistribution layer and electrically connected with the redistribution layer; and
the through-hole connection structure is electrically connected with the redistribution layer.

14. The semiconductor package structure according to claim 13, wherein
the redistribution layer comprises a passivation layer and a metal line layer located in the passivation layer;
the passivation layer is a single-layer or multi-layer stacked structure, and the corresponding metal line layer is a single-layer or multi-layer stacked structure; and
the pads are electrically connected with the metal line layer.

15. The semiconductor package structure according to claim 11, wherein a deep trench capacitor is further formed in the substrate of the bridge chip, the deep trench capacitor being electrically connected with the redistribution layer.

16. A semiconductor package structure, comprising:
a bridge chip, the bridge chip comprising a substrate, the substrate comprising opposed front surface and back surface, the front surface of the substrate having a pad, the substrate having a through-hole connection structure, the back surface of the substrate exposing a surface of one end of the through-hole connection structure, the bridge chip further comprises:
a first metal pillar protruding on the front surface of the substrate and electrically connected with the corresponding pad;
an upper insulation layer covering the first metal pillar and the front surface of the substrate; a second metal pillar protruding on the back surface of the substrate and electrically connected with the corresponding through-hole connection structure; and
a lower insulation layer covering the second metal pillar and the back surface of the substrate;
a first molding layer covering the bridge chip, an upper surface of the first molding layer exposing the surface of one end of the first metal pillar facing away from the front surface of the substrate, the lower surface of the first molding layer exposing the surface of one end of the second metal pillar facing away from the back surface of the substrate;
a first redistribution layer located on the lower surface of the first molding layer and the upper insulation layer, the first redistribution layer being electrically connected with the first metal pillar;
a second redistribution layer located on an upper surface of the upper insulation layer and the first molding layer, the second redistribution layer being electrically connected with the second metal pillar;
a semiconductor chip, the semiconductor chip being mounted on an upper surface of the second redistribution layer, the semiconductor chip being electrically connected with the second redistribution layer;
a second molding layer covering the upper surface of the second redistribution layer and the semiconductor chip; and
a solder bump located on a lower surface of the first redistribution layer and electrically connected with the first redistribution layer.

17. The semiconductor package structure according to claim 16, wherein
the first redistribution layer comprises a first organic dielectric layer and a first metal line layer located in the first organic dielectric layer;
the first organic dielectric layer is a single-layer or multi-layer stacked structure, and the corresponding first metal line layer is a single-layer or multi-layer stacked structure; and
the first redistribution layer is electrically connected with the second metal pillar by the first metal line layer being electrically connected with the second metal pillar.

18. The semiconductor package structure according to claim 16, wherein
the second redistribution layer comprises a second organic dielectric layer and a second metal line layer located in the second organic dielectric layer;
the second organic dielectric layer is a single-layer or multi-layer stacked structure, and the corresponding second metal line layer is a single-layer or multi-layer stacked structure; and
the second redistribution layer further comprises micro pads located on an upper surface of the second organic dielectric layer on a top layer and electrically connected with the second metal line layer.

19. The semiconductor package structure according to claim 18, wherein
the semiconductor chip is mounted on the upper surface of the second redistribution layer;
the semiconductor chip is electrically connected with the second redistribution layer by micro bumps on the semiconductor chip being soldered together with the micro pads; and
the second redistribution layer is electrically connected with the first metal pillar by the second metal line layer being electrically connected with the first metal pillar.

20. The semiconductor package structure according to claim 16, wherein an underfill layer is further filled between the semiconductor chip and the upper surface of the second redistribution layer.
